(19) United States
(12) Patent Application Publication
(10) Pub. No.: US 2016/0043135 A1
(43) Pub. Date: Feb. 11, 2016

(54) SEMICONDUCTOR MEMORY DEVICE AND MANUFACTURING METHOD THEREOF

(71) Applicant: Yoshinori KUMURA, Seoul (KR)

(72) Inventor: Yoshinori KUMURA, Seoul (KR)

(21) Appl. No.: 14/629,052

(22) Filed: Feb. 23, 2015

Related U.S. Application Data
(60) Provisional application No. 62/033,453, filed on Aug. 5, 2014.

(51) Int. Cl. H01L 27/22; H01L 43/08; H01L 43/12; H01L 43/02

(52) U.S. Cl. CPC H01L 27/228; H01L 43/02; H01L 43/08; H01L 43/12; H01L 27/224

(57) ABSTRACT

According to one embodiment, a semiconductor memory device including a memory cell array and peripheral region includes a magnetoresistive element provided in the memory cell array, first contact under the magnetoresistive element and second contact in the peripheral region. A material of the first contact differs from that of the second contact.

### CROSS-REFERENCE TO RELATED APPLICATIONS

This application claims the benefit of U.S. Provisional Application No. 62/033,453, filed Aug. 5, 2014, the entire contents of which are incorporated herein by reference.

### FIELD

Embodiments described herein relate generally to a semiconductor memory device to be applied to, for example, a magnetoresistive random access memory (MRAM) and a manufacturing method thereof.

### BACKGROUND

An MRAM is a general term for a nonvolatile semiconductor memory utilizing the phenomenon in which a resistance of a barrier layer changes depending on the magnetization direction of a ferromagnetic substance. A memory cell of an MRAM is constituted of a magnetic tunnel junction (MTJ) element and a transistor. A bottom electrode contact is formed on one diffusion layer of the transistor, and an MTJ element is formed on the bottom electrode contact. The memory cell and peripheral circuit thereof are generally formed by using the same mask.

### BRIEF DESCRIPTION OF THE DRAWINGS

FIG. 1 is a plan view schematically showing part of a semiconductor memory device according to a first embodiment.

FIG. 2 is a cross-sectional view taken along line II-II of FIG. 1.

FIG. 3 shows cross-sectional views taken along lines IIIA-IIIA and IIIB-IIIB of FIG. 1 and a cross-sectional view showing a transistor of a peripheral circuit.

FIG. 4 is a cross-sectional view showing a manufacturing method of the semiconductor memory device according to the first embodiment.

FIG. 5 is a cross-sectional view showing a manufacturing process subsequent to FIG. 4.

FIG. 6 is a cross-sectional view showing a manufacturing process subsequent to FIG. 5.

FIG. 7 is a cross-sectional view showing a manufacturing process subsequent to FIG. 6.

FIG. 8 is a cross-sectional view showing a manufacturing process subsequent to FIG. 7.

FIG. 9 is a cross-sectional view showing a manufacturing process subsequent to FIG. 8.

FIG. 10 is a cross-sectional view showing a manufacturing process subsequent to FIG. 9.

FIG. 11 is a cross-sectional view showing a manufacturing process subsequent to FIG. 10.

FIG. 12 is a cross-sectional view showing a manufacturing process subsequent to FIG. 11.

FIG. 13 is a cross-sectional view showing a manufacturing process subsequent to FIG. 12.

FIG. 14 is a cross-sectional view showing a semiconductor memory device according to a second embodiment.

FIG. 15 is a cross-sectional view showing a semiconductor memory device according to a third embodiment.

FIG. 16 is a cross-sectional view showing a semiconductor memory device according to a fourth embodiment.

FIG. 17 is a cross-sectional view showing a semiconductor memory device according to a fifth embodiment.

### DETAILED DESCRIPTION

In general, according to one embodiment, a semiconductor memory device including a memory cell array and peripheral region includes a magnetoresistive element provided in the memory cell array, first contact under the magnetoresistive element and second contact in the peripheral region. A material of the first contact differs from that of the second contact.

Hereinafter, the embodiments will be described below with reference to the drawings. It should be noted that in the drawings, identical parts are denoted by identical reference symbols.

### First Embodiment

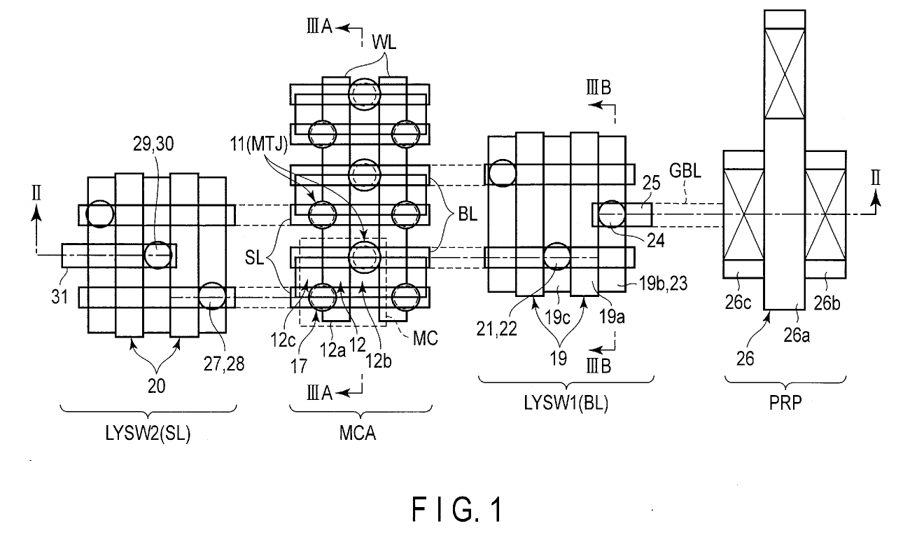

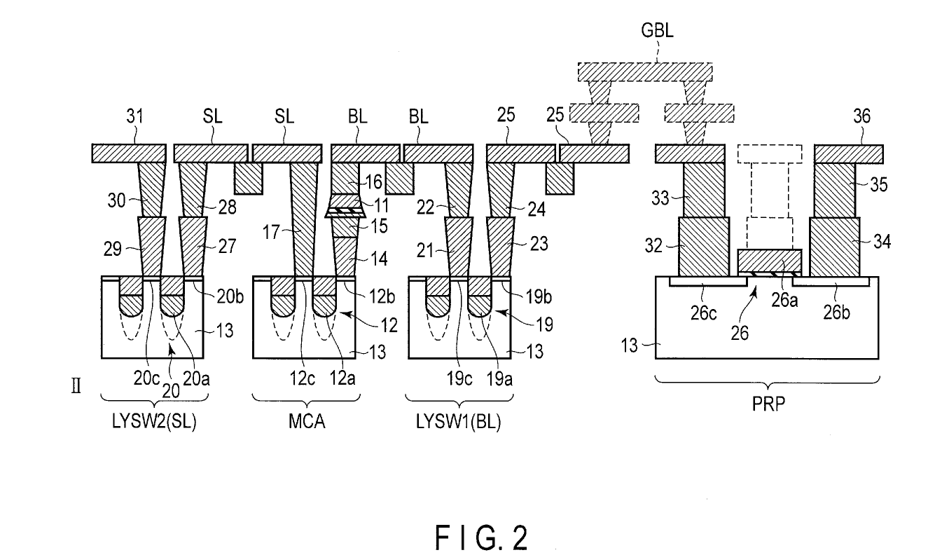

FIG. 1 and FIG. 2 schematically show part of the chip layout of a semiconductor memory device according to a first embodiment, for example, an MRAM. FIG. 1 and FIG. 2 show only the configuration associated with the column direction and the configuration in the row direction is omitted. Further, in FIG. 2, the interlayer insulator is omitted.

In the first embodiment, the configuration of the contact arranged in the memory cell array MCA and connected to an MTJ element 11 is different from the configuration of the contact arranged in the peripheral region other than the memory cell array MCA. The peripheral region includes first and second selection switches SW1 and SW2 arranged on both sides of the memory cell array MCA in the column direction and peripheral circuit PRP.

More specifically, as shown in FIG. 1 and FIG. 2, the configuration of the contact constituted of the bottom electrode contact 14 and bottom electrode 15 which are connected to the MTJ element 11 and one diffusion layer 12b of the transistor 12 is different from the configurations of contact 17 not connected to the MTJ element 11 and connected to the other diffusion layer 12c of the transistor 12, and contacts 23, 21, 27, 29, 34 and 32 connected to the diffusion layers 19b, 19c, 20b, 20c, 26b and 26c of the transistors 19, 20 and 26 arranged in the peripheral region.

A description will specifically be given with reference to FIG. 1 and FIG. 2. As shown in FIG. 1, the memory cell array MCA includes a plurality of memory cells MC. Each memory cell MC is constituted of an MTJ element 11 and transistor 12. As shown in FIG. 2, the transistor 12 is a transistor of an embedded-gate structure in which a gate electrode 12a is embedded in the substitute 13. On both sides of the gate electrode 12a, diffusion layers 12b and 12c each serving as a source-drain region are formed via a gate insulating film (not shown) on the surface area of the substrate 13.

The MTJ element 11 is formed above the diffusion layer 12b of the transistor 12. That is, on the diffusion layer 12b, the bottom electrode contact (BEC) 14 constituted of, for example, titanium (Ti) or titanium nitride (TiN) is formed. On the bottom electrode contact 14, the bottom electrode 15 constituted of, for example, tantalum (Ta) is formed. The material for the bottom electrode contact 14 is not limited to Ti or TiN and tungsten (W) or the like can be applied. Further, the material for the bottom electrode 15 is not limited to Ta, but it is possible to apply one metal selected from, for example, Ti, Cu, Hf, Al, Ni and Co or a compound of B and at least one of Ta, Ti, Cu, Hf, Al, Ni and Co, or the like.

On the bottom electrode 15, the MTJ element 11 is formed. On the MTJ element 11, a top electrode contact (TEC) 16 is formed. The top electrode contact 16 is connected to a bit line BL. The diffusion layer 12c of the transistor 12 is connected to a source line SL through the contact 17. As shown in FIG. 1, the source line SL is arranged parallel to the bit line BL. The gate electrodes 12a of the transistors 12 adjacent in the row direction are connected to each other to thereby constitute a word line WL. The word line WL is arranged in a direction orthogonal to the bit line BL and source line SL.

As shown in FIG. 1, on both sides of the memory cell array MCA in the direction of the bit lines BL, first and second selection switches LYSW1 and LYSW2 serving as column selection switches are arranged. The first selection switch LYSW1 selects the bit line BL and the second selection switch LYSW2 selects the source line SL. The first selection switch LYSW1 includes a plurality of transistors 19 and the second selection switch LYSW2 also includes a plurality of transistors 20. As shown in FIG. 2, each of the transistors 19 and 20 constituting the first and second selection switches LYSW1 and LYSW2 has an embedded gate electrode 19a and 20a. That is, the transistor 12 of the memory cell array MCA and the transistors of the first and second selection switches LYSW1 and LYSW2 are manufactured by the identical process.

The diffusion layer 19c of the transistor 19 constituting the first selection switch LYSW1 is connected to the bit line BL through the contacts 21 and 22. The diffusion layer 19b of the transistor 19 is connected to the transistor 26 included in the peripheral circuit PRP through the contacts 23 and 24, the interconnect 25, global bit line GBL and the like.

The diffusion layer 20b of the transistor 20 constituting the second selection switch LYSW2 is connected to the source line SL through the contacts 27 and 28. The diffusion layer 20c of the transistor 20 is connected to the transistor included in the peripheral circuit through the contacts 29 and 30, an interconnect 31 and global source line (not shown).

The transistor 26 of the peripheral circuit includes a gate electrode 26a, diffusion layers 26b and 26c constituting the source-drain region. The gate electrode 26a is formed on the surface of the substrate 13 via a gate insulating film and diffusion layers 26b and 26c are formed in the surface region of the substrate 13 on both sides of the gate electrode 26a. The diffusion layer 26c is connected to the global bit line GBL through the contacts 32 and 33 and the like and the diffusion layer 26b is connected to the interconnect 36 through the contacts 34 and 35.

The contact 17 formed in the memory cell array MCA, contacts 21, 23, 27 and 29 of the first and second selection switches LYSW1 and LYSW2 and contacts 32 and 34 of the peripheral circuit PRP are constituted of a material identical to the contact 14 connected to the MTJ element 11, such as Ti or TiN.

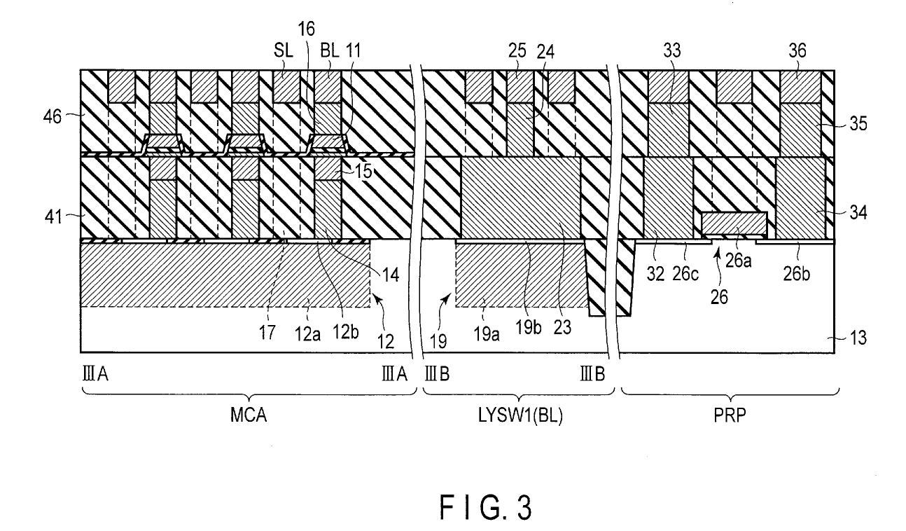

FIG. 3 shows cross-sectional views taken along lines IIIA-IIIA and IIIB-IIIB of FIG. 1 and cross-sectional view taken along line II-II of the transistor 26 of the peripheral circuit.

As described above, in the memory cell array MCA, on the diffusion layer 12b of the transistor 12, the contact 14 constituted of, for example, Ti or TiN is formed and, on this contact 14, the bottom electrode 15 constituted of, for example, Ta is formed and, further on the bottom electrode 15, the MTJ element 11 is formed. Conversely, the contact 17 formed in the memory cell array MCA, contacts 21, 23, 27 and 29 of the first and second selection switches LYSW1, LYSW2 and contacts 32 and 34 of the peripheral circuit PRP are constituted of, for example, Ti or TiN and do not contain Ta. The manufacturing method of the contacts different in shape as shown above will be described below. It should be noted that the second selection switch LYSW2 is manufactured by the process identical to the first selection switch LYSW1 and hence a description thereof is omitted.

### (Manufacturing Method)

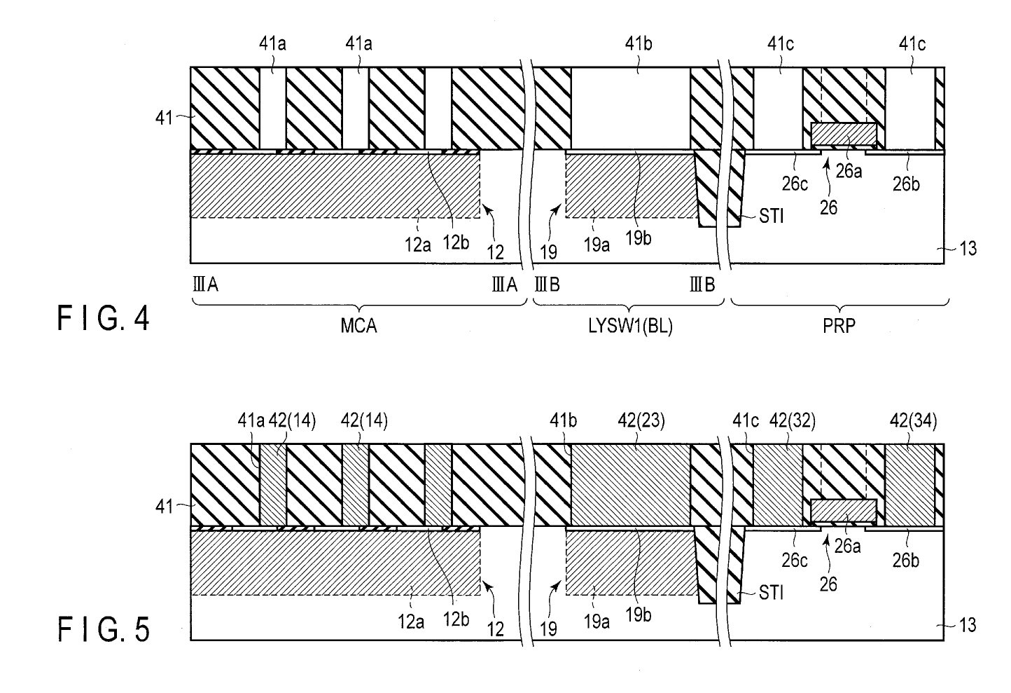

FIGS. 4 to 13 show a manufacturing method of an MRAM of the first embodiment shown in FIG. 3.

As shown in FIG. 4, the shallow trench isolation (STI) serving as an element isolation region is formed in the substrate 13. Thereafter, a transistor 12 constituting the memory cell, a transistor 19 constituting the first selection switch LYSW1 and a transistor 26 constituting the peripheral circuit PRP are formed. That is, an embedded gate electrode 12a of the transistor 12 and an embedded gate electrode 19a of the transistor 19 are formed in the substrate 13. Thereafter, diffusion layers 12b and 12c (not shown) are formed on both sides of the gate electrode 12a and diffusion layers 19b and 19c (not shown) are formed on both sides of the gate electrode 19a. Furthermore, in the peripheral circuit PRP, a gate electrode 26a of the transistor 26 is formed on the substrate 13 and diffusion layers 26b and 26c are formed on both sides of the gate electrode 26a in the substrate 13.

Thereafter, a first interlayer insulator 41 is formed on the entire surface of the substrate 13 and the surface thereof is planarized. As the material for the first interlayer insulator 41, for example, boron phosphorous silicate glass (BPSG) or plasma-tetra ethoxy silane (P-TEOS) is applied.

Subsequently, the first interlayer insulator 41 is selectively removed, then a plurality of contact holes 41a used to expose the diffusion layers 12b (12c) of the transistor 12, a plurality of contact holes 41b used to expose the diffusion layers 19b (19c) of the transistor 19 and a plurality of contact holes 41c used to expose the diffusion layers 26b and 26c of the transistor 26 are formed in the first interlayer insulator 41. Thereafter, a first contact material is formed on the entire surface of the first interlayer insulator 41 and the contact holes 41a, 41b and 41c are thereby embedded. As the first contact material, for example, Ti or TiN is applied.

Subsequently, as shown in FIG. 5, the first contact material is planarized by, for example, chemical mechanical polishing (CMP). In this way, contacts 42 are formed in the contact holes 41a, 41b and 41c. That is, in the memory cell array MCA, the contact 14 connected to the diffusion layer 12b of the transistor 12 is formed, then in the first selection switch LYSW1, the contacts 23 (21) brought into contact with the diffusion layers 19b (19c) of the transistor 19 are formed and, in the peripheral circuit PRP, the contacts 32 and 34 brought into contact with the diffusion layers 26c and 26b of the transistor 26 are formed.

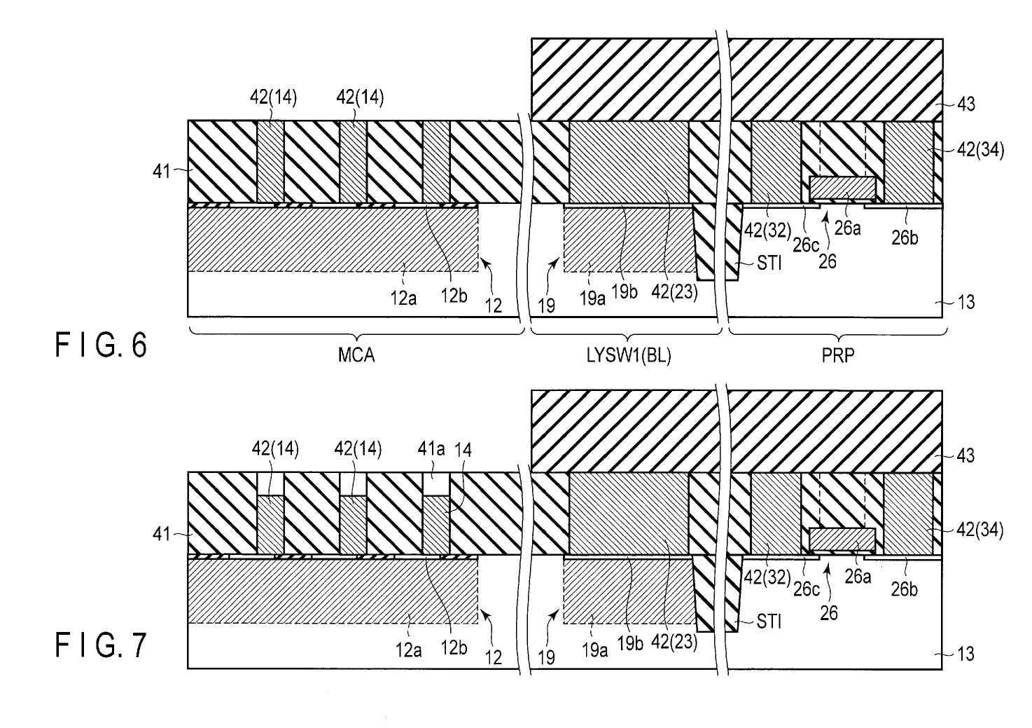

After this, as shown in FIG. 6, a resist film 43 is deposited on a region of the first selection switch LYSW1 and peripheral circuit PRP except the region of the contacts 14 on which the MTJ element of the memory cell array MCA is to be formed.

Next, as shown in FIG. 7, the contacts 42 in the memory cell array MCA are subjected to etch-back by using the resist film 43 as a mask. The depth of the etch-back is, for example, 30 nm. In this way, the bottom electrode contact 14 of the MTJ element is formed in the memory cell array.

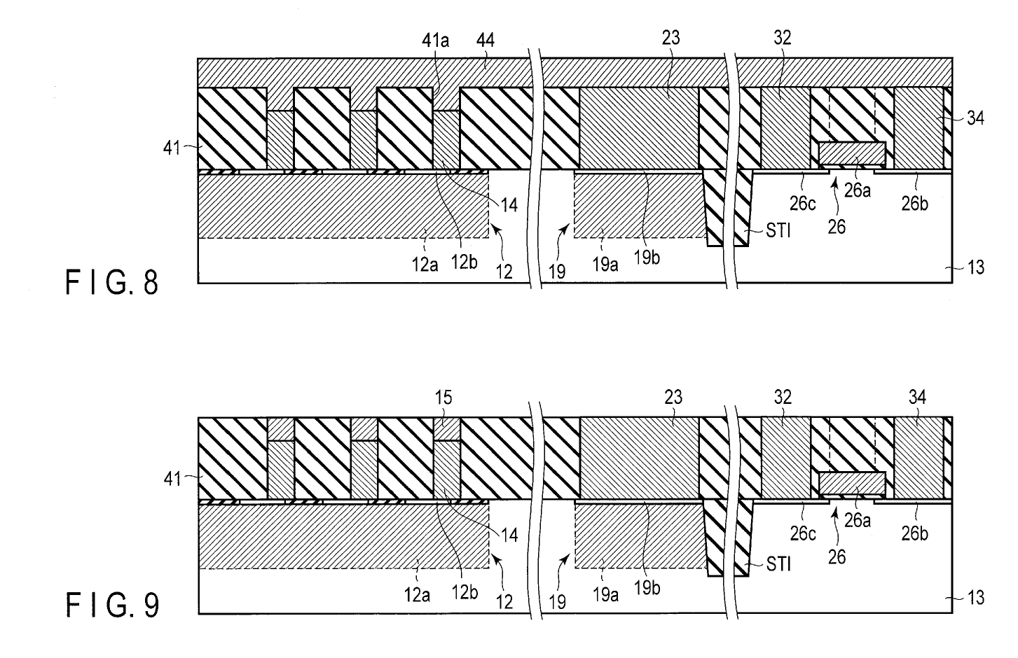

After this, as shown in FIG. 8, after the resist film 43 is removed by ashing, a second material layer 44 is formed on the entire surface of the first interlayer insulator 41 and the contact hole 41a on the bottom electrode contact 14 is embedded by the second material layer 44. As the second material layer 44, for example, Ta is applied. Hereinafter, the second material layer 44 is also referred to as a Ta layer 44.

Next, as shown in FIG. 9, the Ta layer 44 is planarized by CMP by using, for example, the first interlayer insulator 41 as a stopper and the bottom electrode 15 constituted of Ta is formed in the contact hole 41a on the bottom electrode contact 14.

In this state, the part of the Ta layer 44 on the contacts 23 (21) connected to the diffusion layers 19b (19c) of the transistor 19 and the part of the Ta layer 44 on the contacts 34 and 32 connected to the diffusion layers 26b and 26c of the transistor 26 have already been removed.

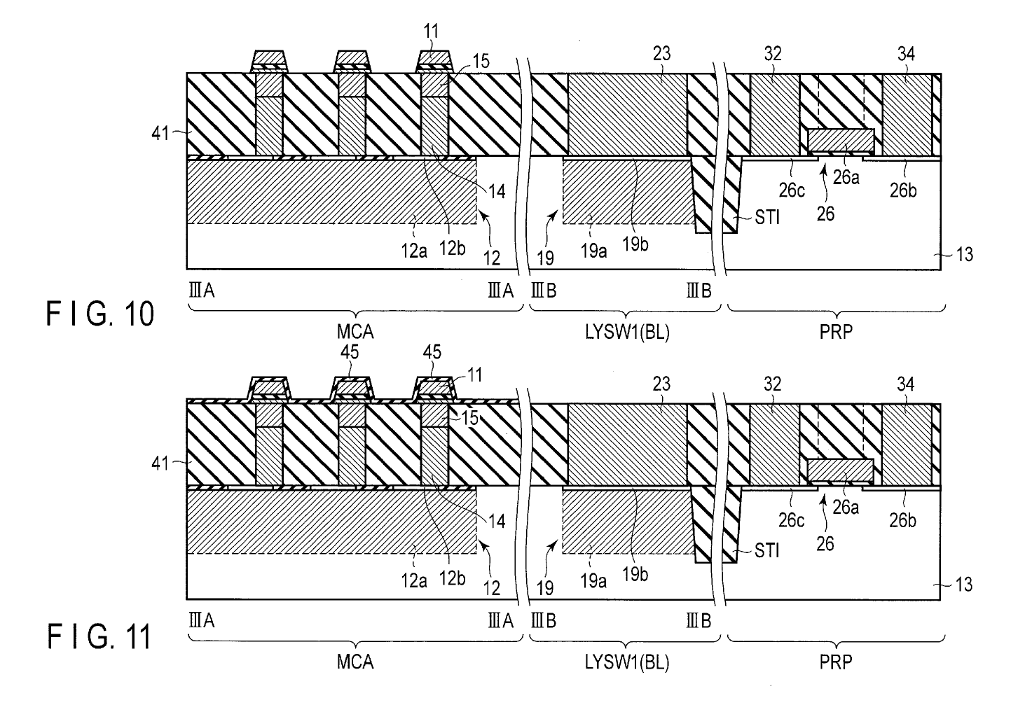

Next, as shown in FIG. 10, the MTJ element 11 is formed on the first interlayer insulator 41 and bottom electrode 15. The MTJ element is constituted of three layers including at least two ferromagnetic layers and barrier layer between these two ferromagnetic layers. Of the two ferromagnetic layers, a layer the magnetization direction of which is fixed is called a fixed layer and layer the magnetization direction of which is inverted by an external magnetic field or by STT is called a free layer. The MTJ element is not limited to the three-layer structure and can be modified. For example, the free layer and fixed layer may be provided with a cap layer. Further, a structure in which one of the boundary faces of the fixed layer not in contact with barrier layer is in contact with an antiferromagnetic layer may be employed. Further, a structure in which the fixed layer includes a first ferromagnetic layer, ruthenium (Ru) and second ferromagnetic layer may be employed. Furthermore, a structure in which the MTJ element 11 includes a first fixed layer, first barrier layer, free layer, second barrier layer and second fixed layer may be employed.

After materials for the ferromagnetic layer and barrier layer each constituting the MTJ element are deposited, a hard mask (not shown) used to process and form the MTJ element 11 is formed on the materials. As the material for the hard mask, for example, TiN, W or the like is used. Next, the materials for the MTJ element are processed by reactive ion etching (RIE) or ion beam etching (IBE) by using the hard mask, whereby the MTJ element 11 is formed.

At the time of the etching, the contact 23 of the first selection switch LYSW1, the contacts 32 and 34 of the peripheral circuit PRP and the first interlayer insulator 41 are etched and a slight step is created at the boundary between the part of the first interlayer insulator 41 associated with the memory cell array MCA and the part of the first interlayer insulator 41 associated with the first selection switch LYSW1 and peripheral circuit PRP as will be described later.

After that, as shown in FIG. 11, a protection film 45 is deposited to suppress oxidation/reduction of the MTJ element 11. As the material for the protection film 45, for example, a silicon nitride film (Si₃N₄) or alumina (Al₂O₃) is applied.

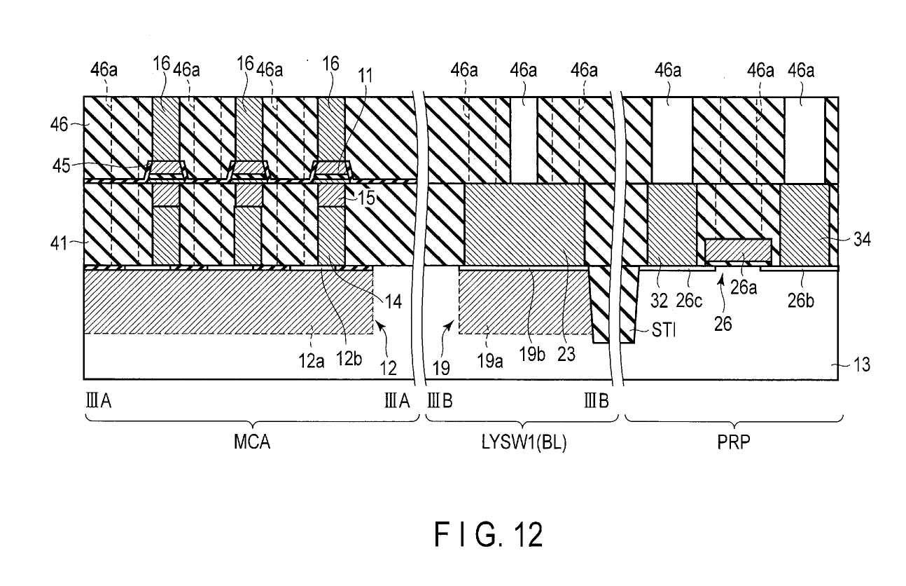

After this, as shown in FIG. 12, a second interlayer insulator 46 is deposited and is planarized. Subsequently, the top electrode contact 16 connected to the MTJ element 11 is formed in the second interlayer insulator 46. Thereafter, a plurality of contact holes 46a are formed in the second interlayer insulator 46. These contact holes 46a are formed at positions corresponding to, for example, the diffusion layer 12c (shown in FIG. 2) of the transistor 12 of the memory cell array MCA, contact 23 of the first selection switch LYSW1 and contacts 32 and 34 of the peripheral circuit PRP and the like.

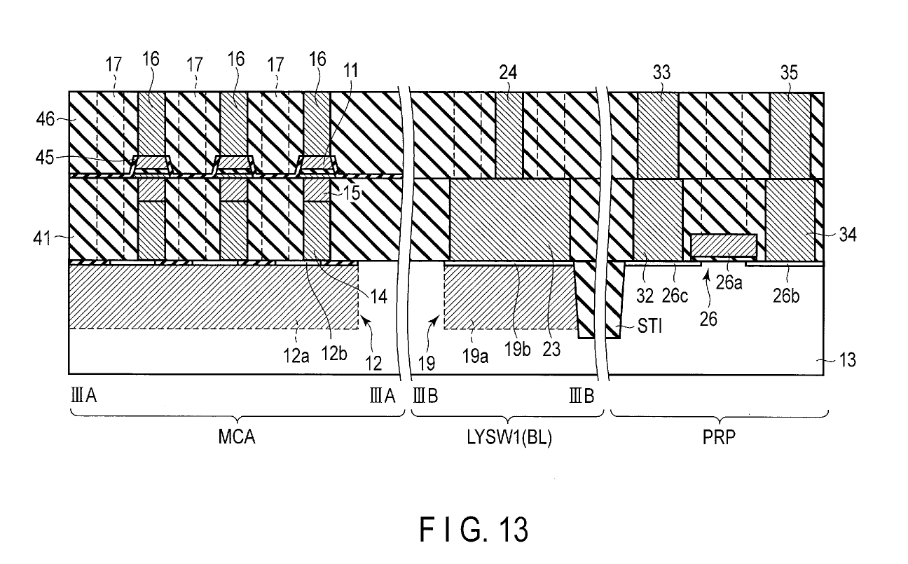

After this, as shown in FIG. 13, a contact material is deposited on the entire surface of the second interlayer insulator 46 and is planarized. As the contact material, for example, one of W, TiN, Cu and the like is used. Thereby, the plurality of contact holes 46a are embedded and the contacts 17, 24, 33 and 35 to be connected to the diffusion layer 12c of the transistor 12, contact 23, contacts 32 and 34 are formed. Here, before the contacts 24, 33 and 35 are formed, the Ta layer has already been removed from the top surfaces of the contact 23 of the first selection switch LYSW1 and contacts 32 and 34 of the peripheral circuit PRP. Accordingly, at the boundary face between each of the contact 23, contacts 32 and 34 and each of the contacts 24, 33 and 35, no tantalum oxide (TaOx) is formed and hence excellent ohmic contact can be formed.

After this, as shown in FIG. 3, a bit line BL is formed on the top electrode contact 16, a source line SL is formed on the contact 17, the interconnect 25 is formed on the contact 24 of the first selection switch LYSW1 and the interconnect 36 is formed on the contact 35 of the peripheral circuit PRP.

According to the first embodiment described above, in the memory cell array MCA, the bottom electrode contact 14 is formed on the diffusion layer 12b of the transistor 12, the bottom electrode 15 constituted of, for example, Ta is formed on the bottom electrode contact 14 and the MTJ element 11 is formed on the bottom electrode 15. Conversely, on the contact 17 on the diffusion layer 12c of the transistor 12 to which the MTJ element 11 is not connected, on the contacts 23 and 21 connected to the diffusion layers 19b and 19c of the transistor 19 constituting the first selection switch LYSW1, on the contacts 27 and 29 connected to the diffusion layers 20b and 20c of transistor 20 constituting the second selection switch LYSW2 and on the contacts 34 and 32 connected to the diffusion layers 26b and 26c of the transistor 26 of the peripheral circuit, no Ta is formed. That is, no Ta is formed on the contacts 23, 21, 27, 29, 34 and 32 connected to the diffusion layers of the transistors except the bottom electrode contact 14 to which the MTJ element 11 is connected. For this reason, no Ta oxide is formed on the contacts 23, 21, 27, 29, 34 and 32. Accordingly, it is possible to prevent contact failure between each of the contacts 23, 21, 27, 29, 34 and 32 and each of the contacts 24, 22, 28, 30, 35 and 33 which are formed on the former contacts from occurring.

### Second Embodiment

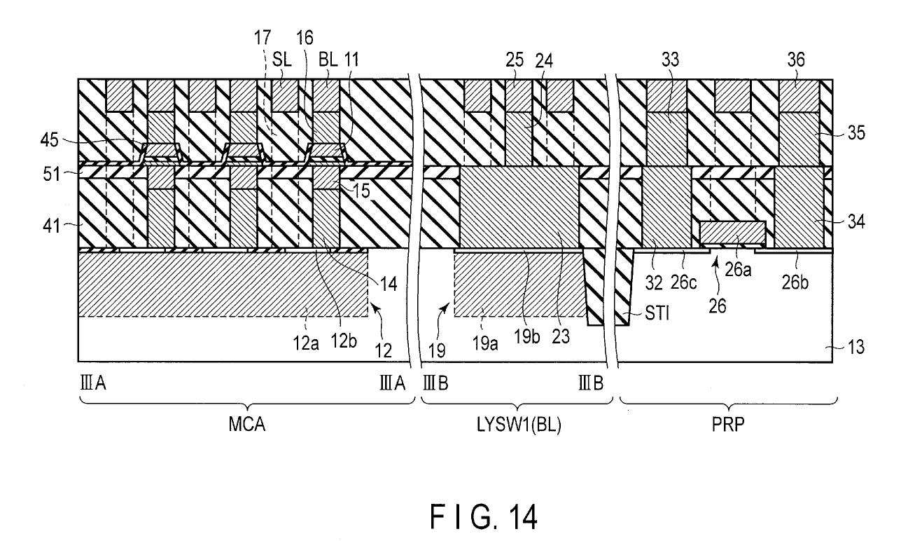

FIG. 14 shows a semiconductor memory device according to a second embodiment.

In the first embodiment, in the memory cell array MCA, the bottom electrode contact 14 and the bottom electrode 15 constituted of Ta are formed in the first interlayer insulator 41 and, in the first and second selection switches LYSW1 and LYSW2 and peripheral circuit PRP, the contacts 23 and 21, the contacts 27 and 29 and the contacts 34 and 32 are formed in the first interlayer insulator 41.

Conversely, in the second embodiment, on the first interlayer insulator 41 covering the memory cell array MCA, first and second selection switches LYSW1 and LYSW2 and peripheral circuit PRP, for example, a silicon nitride film 51 is formed as an insulating film. That is, after the first interlayer insulator 41 is formed, the silicon nitride film 51 is formed on the first interlayer insulator 41. A plurality of contact holes are formed in the silicon nitride film 51 and first interlayer insulator 41. Thereafter, the bottom electrode contact 14 is formed in the contact hole of the memory cell array MCA and contacts 23 and 21, contacts 27 and 29 and contacts 34 and 32 are formed in the contact holes of the first and second selection switches LYSW1 and LYSW2 and peripheral circuit PRP.

Subsequently, a mask is formed on the first selection switch LYSW1 and peripheral circuit PRP, and the bottom electrode contact 14 of the memory cell array MCA is subjected to etch-back. When the bottom electrode contact 14 is subjected to etch-back, if the bottom electrode contact 14 is constituted of, for example, TiN, it is possible to sufficiently secure a selective etching ratio between TiN and the silicon nitride film 51. Accordingly, it is possible to prevent a step from being formed in the silicon nitride film 51 around the contact hole.

After this, for example, a Ta layer is deposited on the entire surface, then the Ta layer is planarized by CMP and a bottom electrode 15 constituted of Ta is formed on the bottom electrode contact 14. When the Ta is embedded on the top of the bottom electrode contact 14, there is no step in the silicon nitride film 51 around the contact hole and hence it is possible to securely remove the Ta layer on the silicon nitride film 51 by CMP. Accordingly, it is possible to accurately form the bottom electrode 15 and it is further possible to excellently connect the bottom electrode 15 and MTJ element 11 to each other.

Conversely, when no silicon nitride film 51 is formed on the first interlayer insulator 41, if the first interlayer insulator 41 is an oxide film and the bottom electrode contact 14 is constituted of TiN, the following problem is caused. That is, when the bottom electrode contact 14 constituted of TiN is subjected to etch-back, a sufficient selective etching ratio cannot be obtained between TiN and oxide film of the first interlayer insulator 41. For this reason, a step is formed in the first interlayer insulator 41 around the contact hole. Accordingly, when Ta is embedded on the top of the bottom electrode contact 14, it is not possible to sufficiently remove the Ta layer on the first interlayer insulator 41 by CMP and Ta remains in the step. When the remained Ta becomes a Ta oxide, it is conceivable that the contact resistance between the bottom electrode 15 and MTJ element 11 increases.

Further, by forming the silicon nitride film 51 on the first interlayer insulator 41, when the MTJ element 11 is formed by etch the material for the MTJ element, it is possible to prevent a step from being formed on the first interlayer insulator 41 and maintain the flatness of the first interlayer insulator 41 and silicon nitride film 51. Accordingly, it is possible in the peripheral region to securely remove the Ta layer on the silicon nitride film 51 and contacts 23, 32 and 34 by CMP. Therefore, it is possible to form excellent ohmic contact between each of the contacts 23, 32 and 34 and each of the contacts 24, 33 and 35 formed on the former contacts.

According to the second embodiment described above, the silicon nitride film 51 is formed on the first interlayer insulator 41. For this reason, it is possible to improve the flatness of the bottom electrode 15 constituted of Ta formed in the silicon nitride film 51 and first interlayer insulator 41. Accordingly, it is possible to stack the ferromagnetic layer and barrier layer constituting the MTJ element 11 to be formed on the bottom electrode 15 in parallel with each other and improve the characteristics (greater coercive force Hc, lower rewrite current and higher magnetoresistive ratio MR) of the MTJ element 11.

Furthermore, in the peripheral region, it is possible to securely remove the Ta layer on the contacts 23, 32 and 34 by CMP. Accordingly, it is possible to improve the performance of the contacts in the peripheral region.

### Third Embodiment

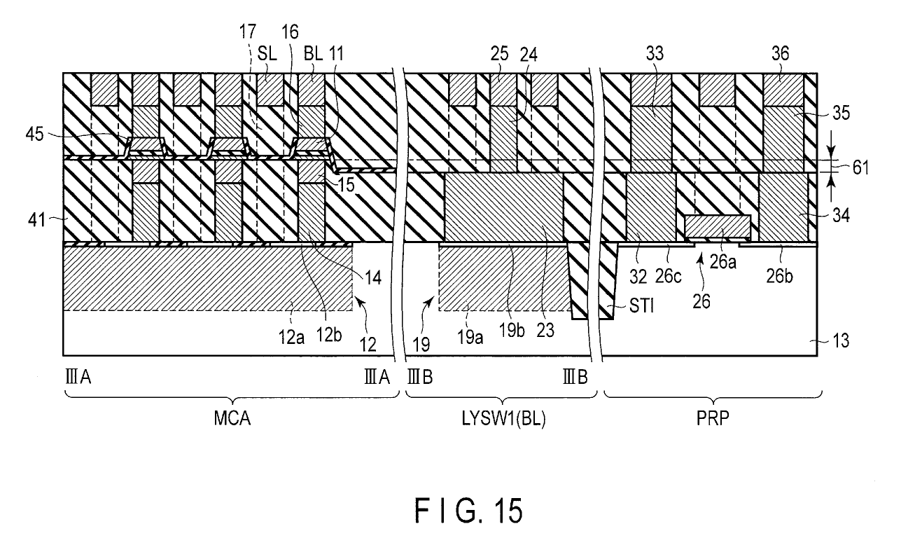

FIG. 15 shows a third embodiment.

In each of the first and second embodiments, the bottom electrode contact 14 in the memory cell array MCA, the contact 23 of the first selection switch LYSW1 and the contacts 32 and 34 of the peripheral circuit PRP have simultaneously been formed by the same manufacturing process. Conversely, in the third embodiment, a bottom electrode contact 14 of the memory cell array MCA, contact 23 of the first selection switch LYSW1 and contacts 32 and 34 of the peripheral circuit PRP are manufacture by separate manufacturing processes by using different masks.

That is, first the contact 23 of the first selection switch LYSW1 and the contacts 32 and 34 of the peripheral circuit PRP are formed in the first interlayer insulator 41 by a method identical to that described above.

After this, the bottom electrode contact 14 and the bottom electrode 15 constituted of Ta which are in the memory cell array MCA are formed in the first interlayer insulator 41. Accordingly, no material for the bottom electrode 15, for example, Ta is formed on the contact 23 of the first selection switch LYSW1 and contacts 32 and 34 of the peripheral circuit PRP.

Subsequently, a ferromagnetic layer, a barrier layer and a ferromagnetic layer constituting the MTJ element 11 are consecutively stacked, thereafter these ferromagnetic layer, barrier layer and ferromagnetic layer are etched by using a mask and the MTJ element 11 is formed. At the time of the etching, the contact 23 of the first selection switch LYSW1, the contacts 32 and 34 of the peripheral circuit PRP and the first interlayer insulator 41 are etched and an aforementioned step 61 is created at the boundary between the part of the first interlayer insulator 41 associated with the memory cell array MCA and the part of first interlayer insulator 41 associated with the first selection switch LYSW1 and peripheral circuit PRP.

After this, by a process identical to the first and second embodiments, a protection film 45, a second interlayer insulator 46, a top electrode contact 16, contacts 17, 24, 33 and 35, a bit line BL, a source line SL, interconnect 25 and interconnect 36 are consecutively formed.

According to the third embodiment, the contact 23 of the first selection switch LYSW1 and the contacts 32 and 34 of the peripheral circuit PRP are manufactured by a manufacturing process separate from that of the bottom electrode contact 14 in the memory cell array MCA. Accordingly, no material for the bottom electrode 15, for example, Ta is formed on the contact 23 of the first selection switch LYSW1 and contacts 32 and 34 of the PRP. Therefore, it is possible to form excellent ohmic contact between each of the contact 23 of the first selection switch LYSW1 and contacts 32 and 34 of the peripheral circuit PRP and each of the contacts 24, 33 and 35 formed on the former contacts.

Further, the contact 23 of the first selection switch LYSW1 and the contacts 32 and 34 of the peripheral circuit PRP are manufactured by a manufacturing process separate from that of the bottom electrode contact 14 in the memory cell array MCA. Accordingly, it is possible to form 23 of the first selection switch LYSW1 and contacts 32 and 34 of the peripheral circuit PRP by using a material different from the material for the bottom electrode contact 14. Therefore, it is possible to make 23 of the first selection switch LYSW1 and s 32 and 34 of the peripheral circuit PRP have further lower resistance.

### Fourth Embodiment

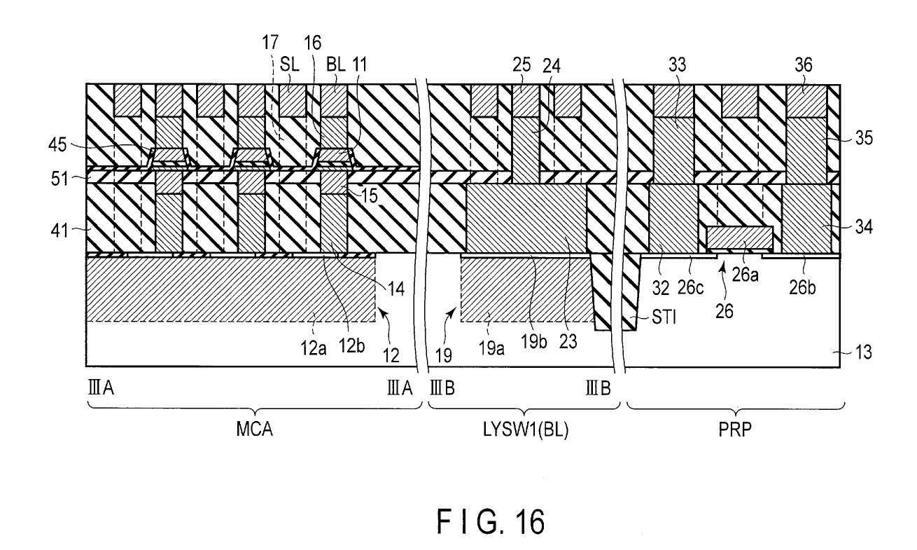

FIG. 16 shows a fourth embodiment. The fourth embodiment is a combination of the third embodiment and second embodiment.

In the fourth embodiment, a contact 23 of the first selection switch LYSW1 and contacts 32 and 34 of the peripheral circuit PRP are manufacturing by a manufacturing process separate from that of a bottom electrode contact 14 in the memory cell array MCA as in the case of the third embodiment.

That is, as in the case of the third embodiment, first the contact 23 of the first selection switch LWSW1 and the contacts 32 and 34 of the peripheral circuit PRP are formed in the first interlayer insulator 41.

Subsequently, as in the case of the second embodiment, a silicon nitride film 51 is formed on the first interlayer insulator 41. After this, a bottom electrode contact 14 and a bottom electrode 15 constituted of Ta which are in the memory cell array MCA are formed in the silicon nitride film 51 and first interlayer insulator 41. Accordingly, no material for the bottom electrode 15, for example, Ta is formed on the contact 23 of the first selection switch LYSW1 and contacts 32 and 34 of the peripheral circuit PRP.

According to the fourth embodiment, it is possible to improve the flatness of the bottom electrode 15 on the bottom electrode contact 14 and a part around the bottom electrode 15 as in the case of the second embodiment. Accordingly, it is possible to improve the characteristics of the MTJ element 11. Further, as in the case of the third embodiment, no material for the bottom electrode 15, for example, Ta is formed on the contact 23 of the first selection switch LYSW1 and contacts 32 and 34 of the peripheral circuit PRP. Accordingly, it is possible to form excellent ohmic contact between each of the contact 23 of the first selection switch LYSW1 and contacts 32 and 34 of the peripheral circuit PRP and each of the contacts 24, 33 and 35 formed on the former contacts.

### Fifth Embodiment

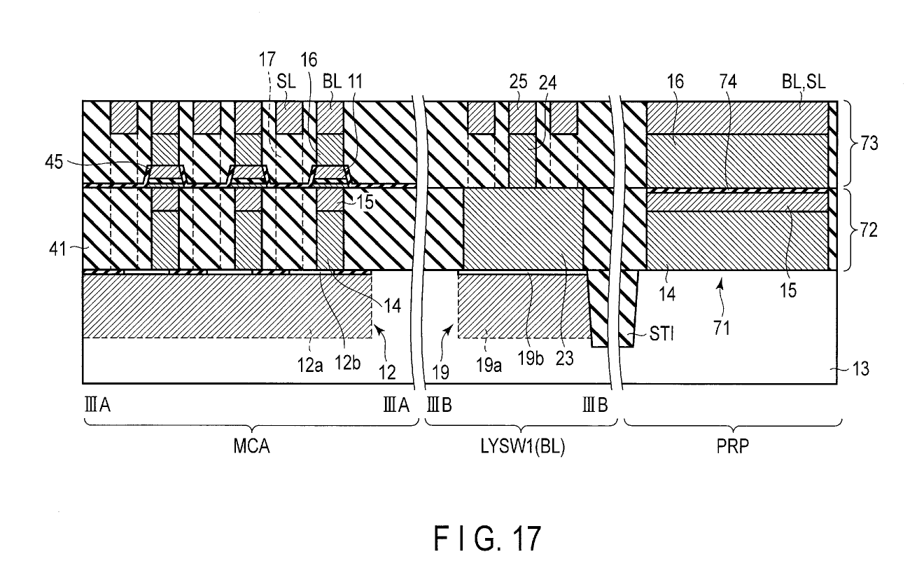

FIG. 17 shows a fifth embodiment.

In each of the first to fourth embodiments, a case where the transistor 26 is formed in the peripheral circuit PRP has been described. Conversely, in the fifth embodiment, a capacitive element is formed in the peripheral circuit PRP.

As shown in FIG. 17, a capacitive element 71 is formed on a substrate 13 of the peripheral circuit PRP. This capacitive element 71 is constituted of a first electrode 72, second electrode 73 and capacitor insulating film 74 provided between the first and second electrodes 72 and 73. The first electrode 72 has the configuration identical to those of, for example, a bottom electrode contact 14 and bottom electrode 15 to be formed in the memory cell array MCA and is manufactured by a process identical to those of the bottom electrode contact 14 and bottom electrode 15. The second electrode 73 has the configuration identical to those of, for example, a top electrode contact 16, bit line BL and source line SL to be formed in the memory cell array MCA and is manufactured by a process identical to those of the top electrode contact 16, bit line BL and source line SL. The capacitor insulating film 74 is constituted of a material for the bottom electrode 15, for example, an oxide (TaOx) of Ta.

The material TaOx serving as a material for the capacitor insulating film 74 has relative dielectric constant of 26, which is greater than 3.9 of that of a silicon oxide and 7.5 of that of a silicon nitride film. Furthermore, the capacitive element 71 using TaOx makes it possible to reduce the area required to obtain the same capacity to 1/7 as compared with, for example, a capacitive element using a silicon oxide. Accordingly, the capacitive element 71 using TaOx makes it is possible to reduce the occupied area.

The capacitive element 71 of this embodiment is applied to, for example, a decoupling (bypass) capacitor or a high-frequency circuit. When the capacitive element 71 is used as a decoupling capacitor, it is possible to suppress a variation in the power supply voltage (noise) by providing the capacitive element 71 at a position, for example, between the power supply and ground.

Further, as an example of a capacitive element applied to a high-frequency circuit, such as a voltage control oscillator (VCO), there is, for example, a MOS capacitor or a metal-insulator-metal (MIM) capacitor. However, the MOS capacitor has a large parasitic resistance component and hence it is difficult to obtain a high Q-value (value expressing the sharpness of a resonance peak) by using the MOS capacitor. Conversely, the capacitive element 71 of this embodiment has a small parasitic resistance component and hence it is possible to obtain a high Q-value by using the capacitive element 71. Accordingly, when the capacitive element 71 of this embodiment is applied to, for example, a VCO, it is possible to oscillate a signal of a stable frequency.

Further, the MIM capacitor has the configuration in which a capacitor insulating film is formed between two metallic electrodes and hence requires a particular manufacturing process. Conversely, the capacitive element 71 of this embodiment can be manufactured by a manufacturing process identical to that of the contact of the semiconductor memory device and hence the capacitive element 71 can be manufactured easily.

According to the fifth embodiment described above, the first electrode 72 constituting the capacitive element 71 has the configuration identical to those of the bottom electrode contact 14 and bottom electrode 15 to be formed in the memory cell array MCA and is manufactured by a process identical to those of the bottom electrode contact 14 and bottom electrode 15. Further, the second electrode 73 has the configuration identical to those of the top electrode contact 16, bit line BL and source line SL to be formed in the memory cell array MCA and is manufactured by a process identical to those of the top electrode contact 16, bit line BL and source line SL. Furthermore, the capacitor insulating film 74 is constituted of an oxide (TaOx) of Ta serving as a material for the bottom electrode 15. For this reason, it is possible to form a capacitive element 71 having a high Q-value and requiring a small occupied area together with a memory cell array MCA. Accordingly, it is possible to provide a capacitive element 71 advantageous to the semiconductor memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device including a memory cell array and a peripheral region comprising:
a magnetoresistive element provided in the memory cell array;
a first contact under the magnetoresistive element; and
a second contact in the peripheral region,
wherein a material of the first contact differs from that of the second contact.

2. The device according to claim 1, wherein
a material for the first contact includes one metal selected from Ta, Ti, Cu, Hf, Al, Ni and Co or a compound of B and at least one of Ta, Ti, Cu, Hf, Al, Ni and Co.

3. The device according to claim 1, wherein
a material for the second contact includes one of W, Ti and TiN.

4. The device according to claim 1, further comprising:
a first interlayer insulator; and
a silicon nitride film provided on the first interlayer insulator,
wherein the first and second contacts are provided in the silicon nitride film and the first interlayer insulator.

5. The device according to claim 1, further comprising:
a first interlayer insulator; and
a silicon nitride film provided on the first interlayer insulator,
wherein the second contact is provided in the first interlayer insulator.

6. The device according to claim 1, further comprising a capacitive element provided in the peripheral region,
wherein the capacitive element includes a first electrode, a second electrode and a capacitor insulating film provided between the first electrode and the second electrode, the first electrode is constituted of a first material and the capacitor insulating film is constituted of an oxide of the first material.

7. A semiconductor memory device comprising:
a memory cell array including a plurality of memory cells, each of which includes a first transistor and a magnetoresistive element, the first transistor comprising a first gate electrode and first source and drain regions;
a first contact constituted of the first material and provided on one of the first source and drain regions, an upper part of the first contact including an electrode constituted of a second material, the magnetoresistive element being provided on the electrode;
a second transistor arranged in a peripheral region other than the memory cell array, the second transistor comprising a second gate electrode and second source drain regions; and
second and third contacts provided on one of the second source and drain regions and constituted of the first material.

8. The device according to claim 7, wherein
a height of a surface of the first contact differs from a height of a surface of the second contact.

9. The device according to claim 8, wherein
the second material includes one metal selected from Ta, Ti, Cu, Hf, Al, Ni and Co or a compound of B and at least one of Ta, Ti, Cu, Hf, Al, Ni and Co.

10. The device according to claim 8, wherein
the first material includes one of W, Ti and TiN.

11. The device according to claim 7, further comprising:
a first interlayer insulator; and
a silicon nitride film provided on the first interlayer insulator,
wherein the first, second and third contacts are provided in the silicon nitride film and the first interlayer insulator.

12. The device according to claim 7, wherein
the second and third contacts in the peripheral region are provided of a material different from the first contact.

13. The device according to claim 7, further comprising:
a first interlayer insulator; and
a silicon nitride film provided on the first interlayer insulator,
wherein the second and third contacts are provided in the first interlayer insulator.

14. The device according to claim 13, wherein
a material of the second and third contacts in the peripheral region is a third material different from the first material.

15. The device according to claim 7, further comprising a capacitive element provided in the peripheral region,
wherein the capacitive element includes a first electrode, a second electrode and a capacitor insulating film provided between the first electrode and the second electrode, the first electrode is constituted of the first material and the capacitor insulating film is constituted of an oxide of the second material.

16. A manufacturing method of a semiconductor memory device comprising:
forming a first interlayer insulator on a substrate, the substrate including a memory cell array and a peripheral region;
forming a first contact hole in the first interlayer insulator of the memory cell array and forming a second contact hole in the first interlayer insulator of the peripheral region;
forming a first material in the first and second contact holes and forming a second contact in the second contact hole;
removing part of the first material in the first contact hole and forming a first contact in the first contact hole;
forming an electrode on the first contact, the electrode being formed of a second material; and
forming a magnetoresistive element on the electrode.

17. The method according to claim 16, wherein
a height of a surface of the first contact differs from a height of a surface of the second contact formed in the second contact hole.

18. The method according to claim 16, further comprising forming a silicon nitride film on the first interlayer insulator before forming the first and second contact holes.

19. The method according to claim 16, wherein
the second contact hole and the first material in the second contact hole are formed before the first contact hole and the first material in the first contact hole are formed.

20. The method according to claim 16, further comprising forming a capacitive element in the first interlayer insulator of the peripheral region, the capacitive element including a first electrode, a second electrode and a capacitor insulating film formed between the first electrode and the second electrode, the first electrode being constituted of the first material and the second material and the capacitor insulating film being constituted of an oxide of the second material.

21. The device according to claim 2, wherein
oxidation of the material for the first contact is easier than that of a material for the second contact.

22. The device according to claim 2, wherein
the first contact comprises:
a first portion comprising a material for the second contact; and
a second portion provided on the first portion, the second portion comprising the material for the first contact.
